(19) United States
(12) Patent Application Publication
(10) Pub. No.: US 2013/0183823 A1
(43) Pub. Date: Jul. 18, 2013

(54) BUMPING PROCESS

(71) Applicants: Chih-Ming Kuo, Hsinchu County (TW); Hua-An Dai, Kaohsiung City (TW); Cheng-Fan Lin, Hsinchu County (TW); Yie-Chuan Chiu, Hsinchu City (TW); Yung-Wei Hsieh, Hsinchu City (TW)

(72) Inventors: Chih-Ming Kuo, Hsinchu County (TW); Hua-An Dai, Kaohsiung City (TW); Cheng-Fan Lin, Hsinchu County (TW); Yie-Chuan Chiu, Hsinchu City (TW); Yung-Wei Hsieh, Hsinchu City (TW)

(73) Assignee: CHIPBOND TECHNOLOGY CORPORATION, Hsinchu (TW)

(21) Appl. No.: 13/352,537

(22) Filed: Jan. 18, 2012

(51) Int. Cl. H01L 21/60

(52) U.S. Cl. 438/613; 257/E21.506

(57) ABSTRACT

A bumping process includes providing a silicon substrate, forming a titanium-containing metal layer on the silicon substrate, wherein the titanium-containing metal layer comprises a plurality of first areas and a plurality of second areas, forming a photoresist layer on the titanium-containing metal layer, patterning the photoresist layer to form a plurality of opening slots corresponded to the first areas of the titanium-containing metal layer, forming a plurality of copper bumps at the opening slots, proceeding a heat procedure, forming a plurality of bump isolation layers on the copper bumps, forming a plurality of connective layers on the bump isolation layers, removing the photoresist layer, removing the second areas and enabling each the first areas to form an under bump metallurgy layer.

### FIELD OF THE INVENTION

The present invention is generally related to a bumping process, which particularly relates to the bumping process which prevents the copper ions from dissociation.

### BACKGROUND OF THE INVENTION

Modern electronic products gradually lead a direction of light, thin, short, and small. Accordingly, layout density of interior circuit for electronic product becomes more concentrated consequentially. However, a short phenomenon is easily occurred in mentioned circuit layout via a relatively short gap between two adjacent electronic connection devices.

### SUMMARY

The primary object of the present invention is to provide a bumping process comprising the steps of providing a silicon substrate having a surface, a plurality of bond pads disposed on said surface, and a protective layer disposed on said surface, wherein the protective layer comprises a plurality of openings, and the bond pads are revealed by the openings; forming a titanium-containing metal layer on the silicon substrate, said titanium-containing metal layer covers the bond pads and the protective layer, and the titanium-containing metal layer comprises a plurality of first areas and a plurality of second areas located outside the first areas; forming a photoresist layer on the titanium-containing metal layer; patterning the photoresist layer to form a plurality of opening slots, wherein each of the opening slots is corresponded to each of the first areas of the titanium-containing metal layer and comprises an inner lateral surface; forming a plurality of copper bumps at the opening slots, each of the copper bumps comprises a first top surface and a first ring surface; proceeding a heating procedure to ream the opening slots, mentioned heating procedure makes an interval space located between the inner lateral surface of each of the opening slots and the first ring surface of each of the copper bumps; forming a plurality of bump isolation layers at the interval spaces, the first top surfaces of the copper bumps and the first ring surfaces, and each of the bump isolation layers comprises a second top surface; forming a plurality of connective layers on the second top surfaces of the bump isolation layers; removing the photoresist layer; removing the second areas of the titanium-containing metal layer and enabling each of the first areas of the titanium-containing metal layer to form an under bump metallurgy layer located under each of the bump isolation layers. Owning to the reason that each of the bump isolation layers covers each of the copper bumps, a short phenomenon occurred between two adjacent copper bumps via dissociation of copper ions can be prevented. Besides, the bump isolation layers may prevent dissociation of copper ions from the copper bumps, the space located between two adjacent copper bumps can be effectively reduced.

### DESCRIPTION OF THE DRAWINGS

FIG. 1 is a manufacturing flow illustrating a bumping process in accordance with a preferred embodiment of the present invention.

FIGS. 2A to 2J are section diagrams illustrating the bumping process in accordance with a preferred embodiment of the present invention.

### DETAILED DESCRIPTION OF THE INVENTION

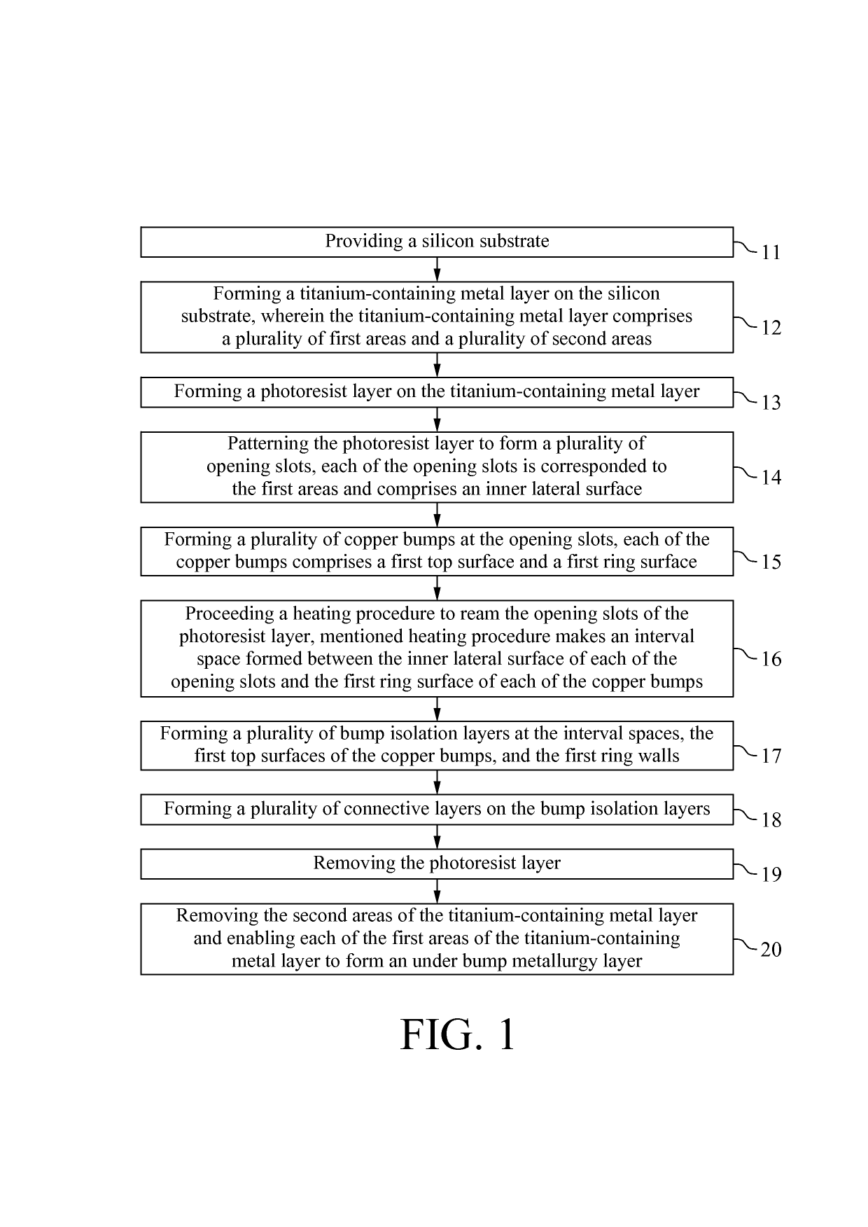

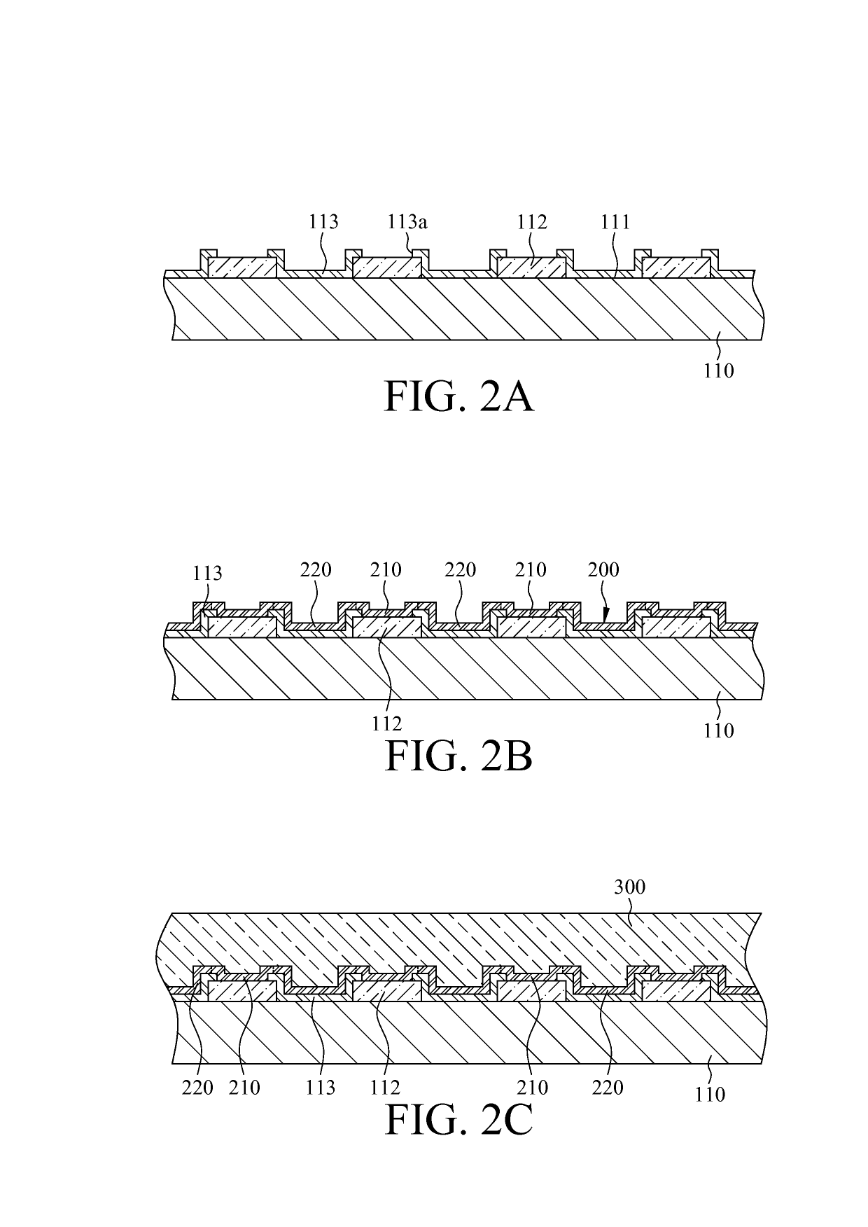

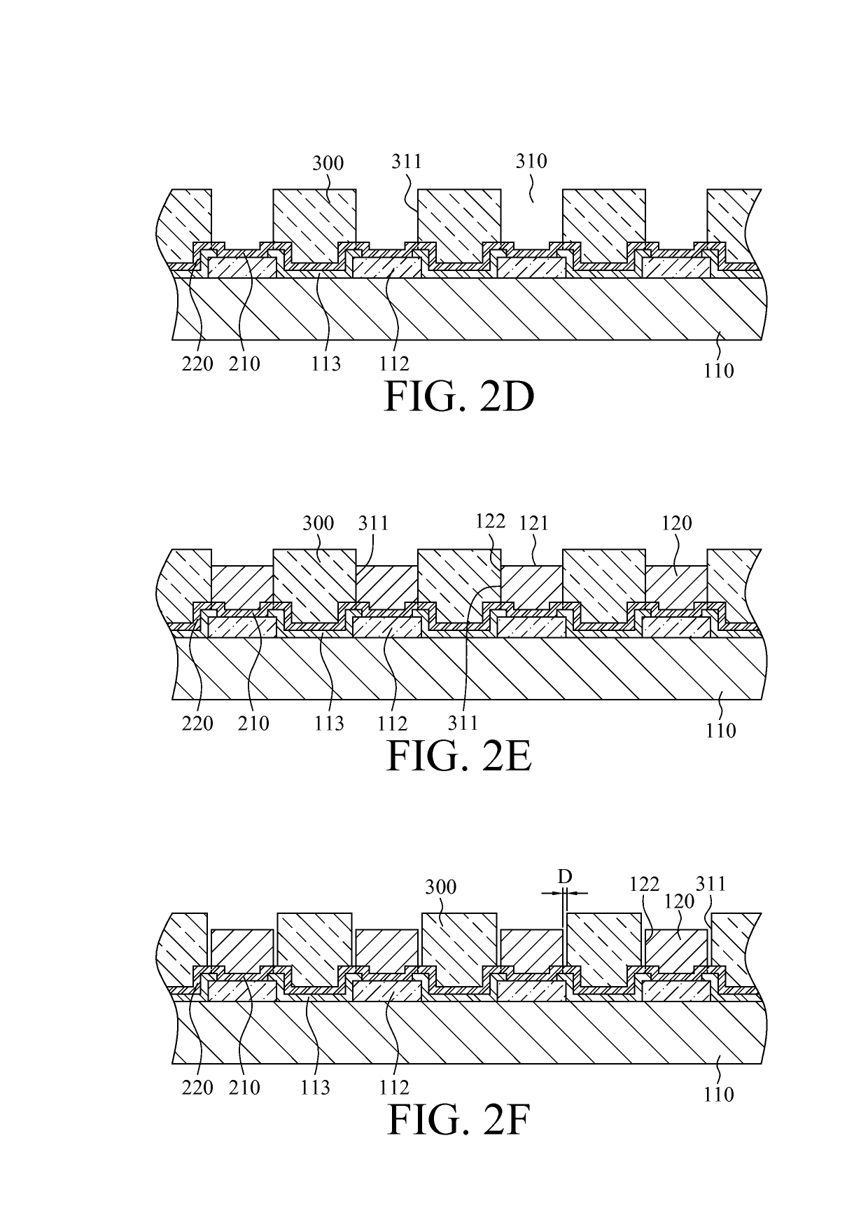

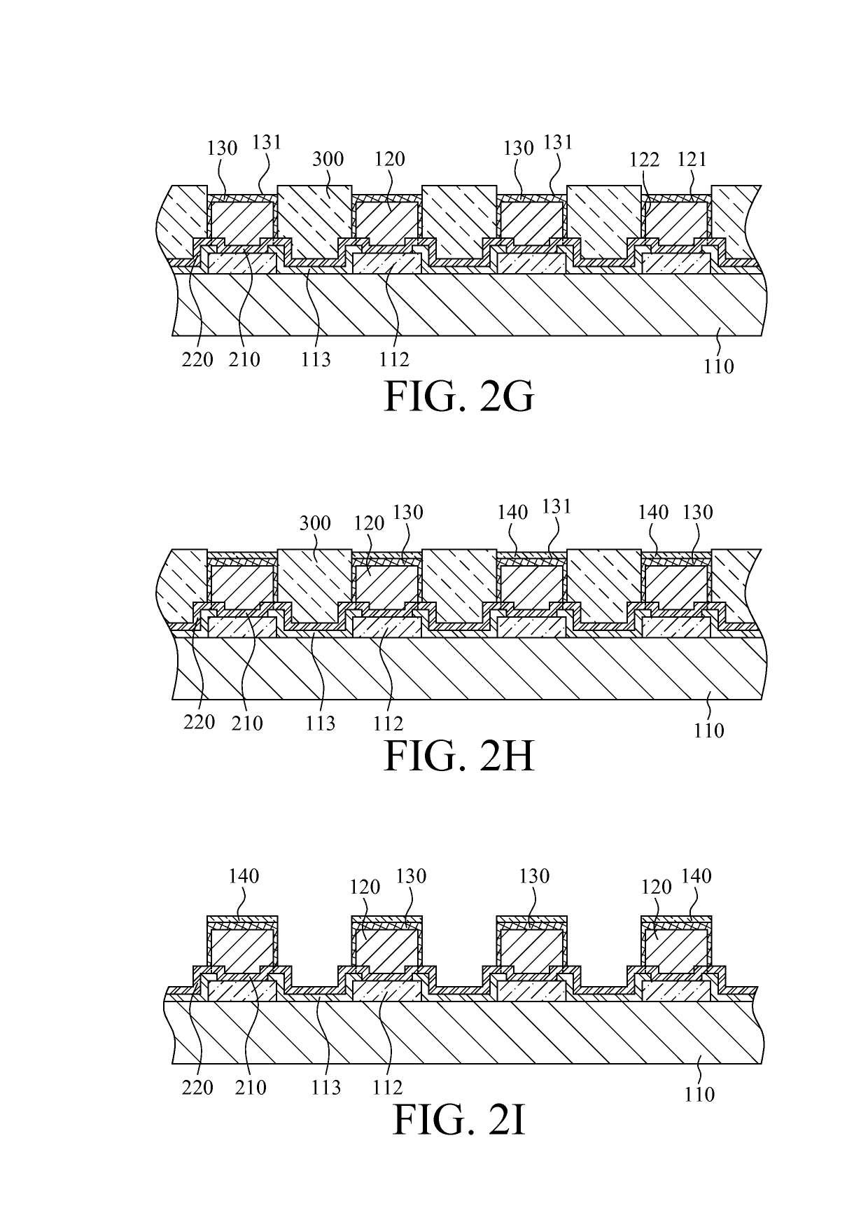

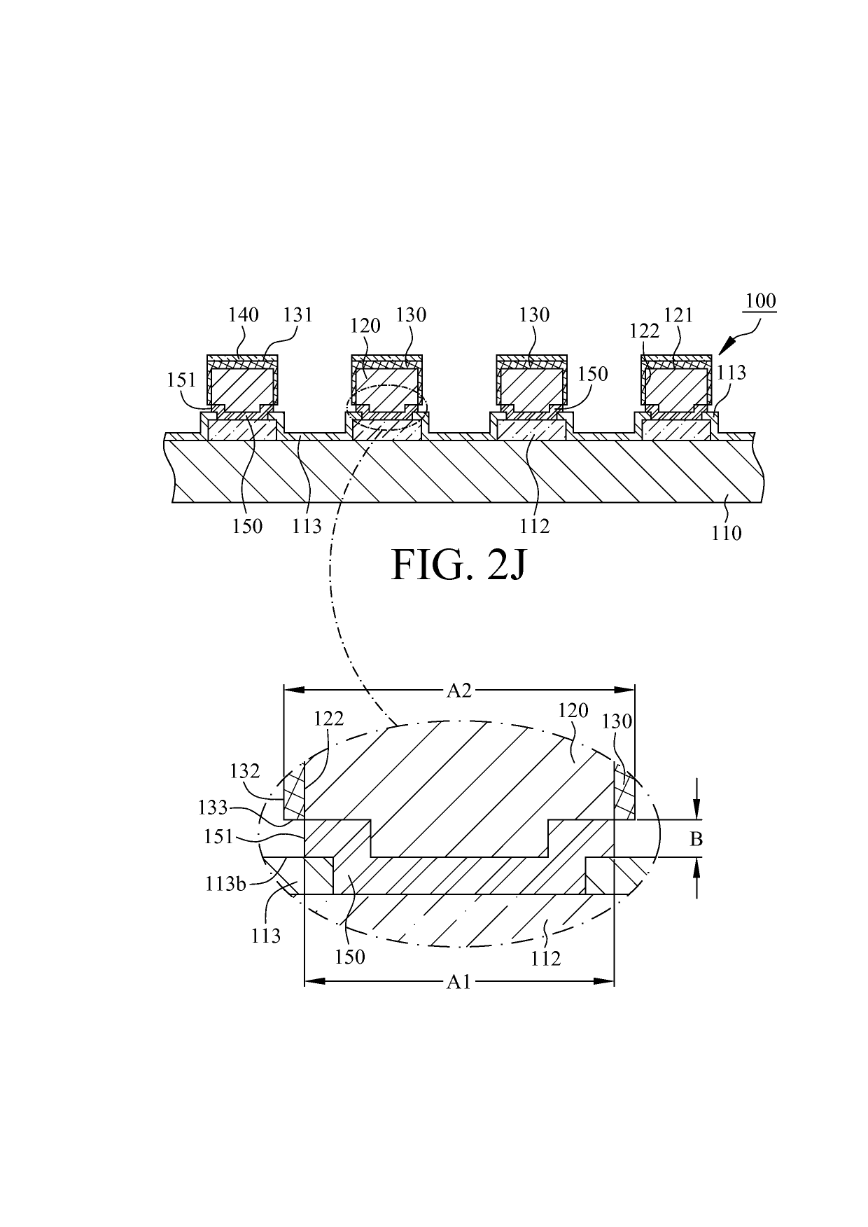

With reference to FIGS. 1 and 2A-2J, a bumping process in accordance with a preferred embodiment of the present invention comprises the steps described as followed. First, referring to step 10 of FIG. 1 and FIG. 2A, providing a silicon substrate 110 having a surface 111, a plurality of bond pads 112 disposed on said surface 111, and a protective layer 113 disposed on said surface 111, wherein the protective layer 113 comprises a plurality of openings 113a, and the bond pads 112 are revealed by the openings 113a. Next, with reference to step 11 of FIG. 1 and FIG. 2B, forming a titanium-containing metal layer 200 on the silicon substrate 110, wherein the titanium-containing metal layer 200 covers the bond pads 112 and the protective layer 113, and said titanium-containing metal layer 200 comprises a plurality of first areas 210 and a plurality of second areas 220 located outside the first areas 210. Thereafter, referring to step 12 of FIG. 1 and FIG. 2C, forming a photoresist layer 300 on the titanium-containing metal layer 200. Then, referring to step 13 of FIG. 1 and FIG. 2D, patterning the photoresist layer 300 to form a plurality of opening slots 310, wherein each of the opening slots 310 is corresponded to each of the first areas 210 of the titanium-containing metal layer 200 and comprises an inner lateral surface 311. Afterwards, with reference to step 14 of FIG. 1 and FIG. 2E, forming a plurality of copper bumps 120 at the opening slots 310, each of the copper bumps 120 comprises a first top surface 121 an a first ring surface 122. In this embodiment, the first ring surface 122 of each of the copper bumps 120 is in contact with the inner lateral surface 311 of each of the opening slots 310.

Thereafter, with reference to step 15 of FIG. 1 and FIG. 2F, proceeding a heating procedure to ream the opening slots 310, mentioned heating procedure makes an interval space D located between the inner lateral surface 311 of each of the opening slots 310 and the first ring surface 122 of each of the copper bumps 120. In this embodiment, the glass transition temperature in the heating procedure ranges from 70 to 140 degrees. Afterwards, referring to step 16 of FIG. 1 and the FIG. 2G, forming a plurality of bump isolation layers 130 at the interval spaces D, the first top surfaces 121 of the copper bumps 120 and the first ring surfaces 122, and each of the bump isolation layers 130 comprises a second top surface 131. The material of the bump isolation layers 130 can be selected from one of nickel, palladium or gold. Then, referring to step 17 of FIG. 1 and FIG. 2H, forming a plurality of connective layers 140 on the second top surfaces 131 of the bump isolation layers 130. In this embodiment, the material of the connective layers 140 can be gold. Next, referring to step 18 of FIG. 1 and FIG. 21, removing the photoresist layer 300. Eventually, with reference to step 19 of FIG. 1 and FIG. 2J, removing the second areas 220 of the titanium-containing metal layer 200 and enabling each of the first areas 210 of the titanium-containing metal layer 200 to form an under bump metallurgy layer 150 located under each of the bump isolation layers 130. The under bump metallurgy layer 150 can be selected from one of titanium/tungsten/gold, titanium/copper, or titanium/tungsten/copper.

Referring to FIG. 2J again, each of the under bump metallurgy layers 150 comprises a second ring surface 151 having a first outer circumference A1, each of the bump isolation layers 130 further comprises a third ring surface 132 having a second circumference A2, and said second circumference A2 is not smaller than the first circumference A1. Besides, each of the second ring surfaces 151 is coplanar with the first ring surface 122 of each of the copper bumps 120. In this embodiment, the protective layer 113 further comprises an exposing surface 113b, each of the bump isolation layers 130 further comprises a bottom surface 133, and a gap B is located between the exposing surface 113b and the bottom surface 133. Owning to the reason that each of the bump isolation layers 130 covers each of the copper bumps 120, a short phenomenon occurred between two adjacent copper bumps 120 via dissociation of copper ions can be prevented. Besides, the bump isolation layers 130 may prevent dissociation of copper ions from adjacent copper bumps 120 so that the interval between two adjacent copper bumps 120 can be effectively reduced.

While this invention has been particularly illustrated and described in detail with respect to the preferred embodiments thereof, it will be clearly understood by those skilled in the art that it is not limited to the specific features and describes and various modifications and changes in form and details may be made without departing from the spirit and scope of this invention.

1. A bumping process at least comprising:
providing a silicon substrate having a surface, a plurality of bond pads disposed on said surface, and a protective layer disposed on said surface, wherein the protective layer comprises a plurality of openings, and the bond pads are revealed by the openings;
forming a titanium-containing metal layer on the silicon substrate, wherein the titanium-containing metal layer covers the bond pads and the protective layer, and said titanium-containing metal layer comprises a plurality of first areas and a plurality of second areas located outside the first areas;
forming a photoresist layer on the titanium-containing metal layer;
patterning the photoresist layer to form a plurality of opening slots, wherein each of the opening slots corresponds to each of the first areas of the titanium-containing metal layer and comprises an inner lateral surface;
forming a plurality of copper bumps at the opening slots, wherein each of the copper bumps comprises a first top surface and a first ring surface;
proceeding a heating procedure to ream the opening slots, wherein the heating procedure makes an interval space located between the inner lateral surface of each of the opening slots and the first ring surface of each of the copper bumps;
forming a plurality of bump isolation layers at the interval spaces, the first top surfaces of the copper bumps and the first ring surfaces, and wherein each of the bump isolation layers comprises a second top surface;
forming a plurality of connective layers on the second top surfaces of the bump isolation layers;
removing the photoresist layer; and
removing the second areas of the titanium-containing metal layer and enabling each of the first areas of the titanium-containing metal layer to form an under bump metallurgy layer located under each of the bump isolation layers.

2. The bumping process in accordance with claim 1, wherein each of the under bump metallurgy layers comprises a second ring surface having a first outer circumference, each of the bump isolation layers comprises a third ring surface having a second circumference, and said second circumference is not smaller than the first circumference.

3. The bumping process in accordance with claim 1, wherein each of the under bump metallurgy layers comprises a second ring surface, and each of the second ring surfaces is coplanar with each of the first ring surfaces.

4. The bumping process in accordance with claim 1, wherein the material of the under bump metallurgy layer is selected from one of titanium/tungsten/gold, titanium/copper, or titanium/tungsten/copper.

5. The bumping process in accordance with claim 1, wherein the glass transition temperature in the heating procedure ranges from 70 to 140 degrees Celsius.

6. The bumping process in accordance with claim 1, wherein the material of the connective layers is gold.

7. The bumping process in accordance with claim 1, wherein the material of the bump isolation layers is chosen from one of nickel, palladium or gold.

8. The bumping process in accordance with claim 1, wherein in the step of forming the copper bumps at the opening slots, the first ring surface of each of the copper bumps is in contact with the inner lateral surface of each of the opening slots.

9. The bumping process in accordance with claim 1, wherein the protective layer further comprises an exposing surface, each of the bump isolation layers further comprises a bottom surface, and a gap is located between the exposing surface and the bottom surface.
